(19) United States
(12) Patent Application Publication
(10) Pub. No.: US 2022/0049349 A1
(43) Pub. Date: Feb. 17, 2022

(54) METHOD FOR FORMING A THIN FILM

(71) Applicant: EUGENE TECHNOLOGY CO., LTD., Yongin-si, Gyeonggi-do (KR)

(72) Inventors: Jin Woong KIM, Seoul (KR); Seung Woo SHIN, Hwaseong-si, Gyeonggi-do (KR); Cha Young YOO, Suwon-si, Gyeonggi-do (KR); Woo Duck JUNG, Suwon-si, Gyeonggi-do (KR); Doo Yeol RYU, Cheongju-si, Chungcheongbuk-do (KR); Sung Kil CHO, Yongin-si, Gyeonggi-do (KR); Ho Min CHOI, Hwaseong-si, Gyeonggi-do (KR); Wan Suk OH, Icheon-si, Gyeonggi-do (KR); Koon Woo LEE, Yongin-si, Gyeonggi-do (KR); Ki Ho KIM, Yongin-si, Gyeonggi-do (KR)

(73) Assignee: EUGENE TECHNOLOGY CO., LTD., Yongin-si, Gyeonggi-do (KR)

(21) Appl. No.: 17/275,335

(22) PCT Filed: Sep. 9, 2019
(86) PCT No.: PCT/KR2019/011646

§ 371 Date: Mar. 11, 2021

(30) Foreign Application Priority Data
Sep. 11, 2018 (KR) 10-2018-0108446

(51) Int. Cl. C23C 16/40; C23C 16/52

(52) U.S. Cl. CPC C23C 16/401; C23C 16/52

(57) ABSTRACT

According to an embodiment of the present invention, a method for forming a thin film includes loading an object to be processed into a chamber, and while controlling the temperature of the object to be processed to be 400° C. or less, supplying an Si source gas and an oxidizing gas into the chamber to form a silicon oxide film on the surface of the object to be processed, wherein the oxidizing gas is heated to a temperature exceeding 400° C. before being supplied into the chamber.

### BACKGROUND

The present disclosure relates to a method for forming a thin film, and more specifically, to a method capable of forming a thin film at a low temperature.

In recent years, there has been a demand for a thin film formed at a low temperature, and a thin film formed at an extremely low temperature of 400° C. or less has been studied. Particularly, the present invention is to provide a process for forming a thin film, the process capable of improving the average roughness of a thin film than the prior art.

### SUMMARY

The present disclosure provides a method capable of forming a thin film at a low temperature.

The present disclosure also provides a method for forming a thin film, the method capable of improving the surface roughness of a thin film.

Other purposes of the present invention will become clearer by the following detailed description and the accompanying drawings.

In accordance with an exemplary embodiment of the present invention, provided is a method for forming a thin film, the method including loading an object to be processed into a chamber, and while controlling the temperature of the object to be processed to be 400° C. or less, supplying an Si source gas and an oxidizing gas into the chamber to form a silicon oxide film on the surface of the object to be processed, wherein the oxidizing gas is heated to a temperature exceeding 400° C. before being supplied into the chamber.

The oxidizing gas may be supplied in a pyrolyzed state into the chamber at a temperature lower than the temperature of the object to be processed.

The oxidizing gas may be heated to a temperature of 700-900° C.

The oxidizing gas may be either N₂O or O₂, and the flow rate thereof supplied into the chamber may be 3000-7000 SCCM.

The Si source gas may be either silane or disilane, and the flow rate thereof supplied into the chamber may be 50-100 SCCM.

The pressure inside the chamber may be 25-150 Torr.

The method may further include a step of forming an upper thin film on an upper portion of the silicon oxide film, wherein the upper thin film may be any one of an amorphous silicon thin film doped with boron (B), an undoped amorphous silicon thin film, and an amorphous silicon thin film doped with phosphorus (P).

The silicon oxide film may be 3 Å thick.

The method may further include a step of forming an underlayer before forming the silicon oxide film and then forming the silicon oxide film on an upper portion of the underlayer, wherein the underlayer may be any one of a thermal oxide film, a silicon nitride film, and an amorphous carbon film.

In accordance with another exemplary embodiment of the present invention, an apparatus for forming a thin film includes a chamber having an internal space blocked from the outside and in which a process is performed in the internal space thereof, a susceptor installed in the chamber to have an object to be processed placed thereon and having a built-in heater, a silicon source gas supplier in which a silicon source gas is stored, an oxidizing gas source supplier in which an oxidizing gas is stored, a carrier gas supplier in which a carrier gas is stored, a silicon source supply line connected to the silicon source gas supplier to supply the silicon source gas into the chamber, a carrier gas supply line connected to the carrier gas supplier to supply the carrier gas into the chamber, a main supply line connected to the silicon source supply line and the carrier gas supply line in the state of being connected to the chamber, an oxidizing gas supply line connected to the main supply line to be connected to the oxidizing gas source supplier and supplying the oxidizing gas into the chamber, and an oxidizing gas heater installed in the oxidizing gas supply line to heat the oxidizing gas to a temperature exceeding 400° C.

### BRIEF DESCRIPTION OF THE DRAWINGS

FIG. 1 is a view schematically showing a thin film forming apparatus according to an embodiment of the present invention;

FIG. 2 and FIG. 3 are graphs showing thin film formation rates according to the temperature of an object to be processed when an oxidizing gas is heated and supplied and when an oxidizing gas is not heated and supplied;

FIG. 4 is a graph showing the average roughness of a thin film with respect to the same underlayer;

FIG. 5 is a graph showing the average roughness of a thin film with respect to various underlayers;

FIG. 6 is a graph showing the average roughness of a thin film in accordance with the thickness of a silicon oxide film;

FIG. 7 is a graph showing the average roughness of a thin film in accordance with the temperature of an object to be processed;

FIG. 8 is a graph showing the thin film formation rate according to the heating temperature of an oxidizing gas with respect to the temperature of various objects to be processed;

FIG. 9 is a graph showing the thin film formation rate in accordance with the flow rate of an oxidizing gas;

FIG. 10 is a graph showing the thin film formation rate in accordance with process pressure; and

FIG. 11 is a graph showing the thin film formation rate in accordance with the flow rate of an Si source gas.

### DETAILED DESCRIPTION OF EMBODIMENTS

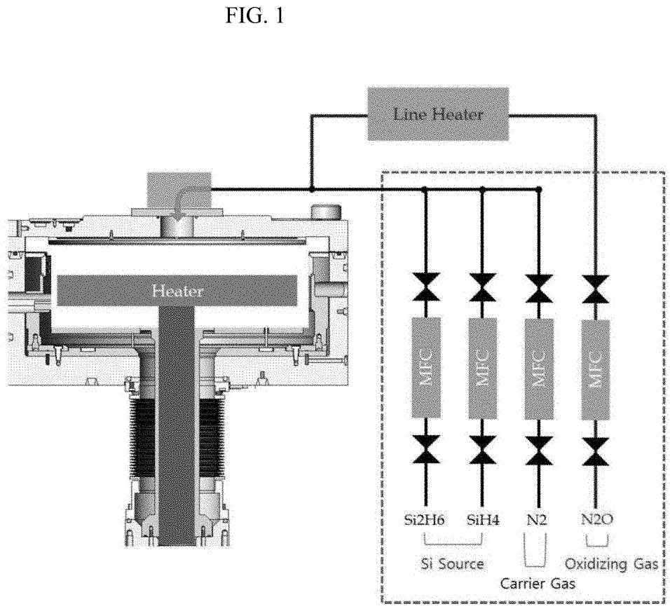

Hereinafter, preferred embodiments of the present invention will be described in more detail with reference to the accompanying FIG. 1 to FIG. 11. Embodiments of the present invention may be modified into various forms, and the scope of the present invention should not be construed as being limited to the embodiments described below. The present embodiments are provided to more fully describe the present invention to those skilled in the art to which the present invention pertains. Accordingly, the shape of each element shown in the figures may be exaggerated to emphasize a clearer description.

FIG. 1 is a view schematically showing a thin film forming apparatus according to an embodiment of the present invention. The apparatus for forming a thin film has a chamber blocked from the outside, and a susceptor on which the object to be processed (or substrate) is placed is installed in the chamber. A thin film is formed on the surface of the object to be processed in the state of being placed on the susceptor, and the susceptor may heat the object to be processed to a required process temperature though a built-in heater.

As a silicon source (Si source) gas, silane or disilane may be selectively used as needed (or other silicon source gases are available), and as a carrier gas, nitrogen (N₂) may be used. A silicon source gas supplier and a carrier gas supplier may be connected to one main supply line connected to the chamber and supplied to the chamber together.

As an oxidizing gas, nitric oxide (N₂O), oxygen (O₂), or H2O may be used. An oxidizing gas supplier may be connected to a supply line connected to the chamber and supplied to the chamber. At this time, a line heater may be installed on the supply line, and the oxidizing gas may be supplied to the chamber in the state of being heated to a required process temperature though the line heater. Since the line heater is known in the art, a detailed description thereof will be omitted.

When describing a method for forming a silicon oxide film through FIG. 1, the object to be processed is controlled to be at a required process temperature/pressure in the state of being placed on the susceptor in the chamber. The process temperature may be controlled through the heater installed in the susceptor, and the process pressure may be controlled through an exhaust line/pump (not shown) connected to the chamber. The process temperature may be 400° C. or less.

Thereafter, the silicon source gas and the carrier gas are supplied through the main supply line, and the oxidizing gas is supplied through the supply line. At this time, the silicon source gas and the carrier gas are supplied at room temperature, but the oxidizing gas is supplied in the state of being heated through the line heater.

Since the line heater heats the oxidizing gas to a temperature above a pyrolysis temperature, the oxidizing gas is supplied into the chamber in a pyrolyzed state. However, since the oxidizing gas is naturally cooled before being supplied into the chamber and the chamber adopts a cold wall method, the temperature of the oxidizing gas supplied into the chamber may be less than 100° C. However, the oxidizing gas remains to be in a pyrolyzed state, so that there is no influence in forming the silicon oxide film. In addition, when the temperature of the oxidizing gas is higher than the temperature of the object to be processed (or substrate), an underlayer formed on the object to be processed may be affected. Therefore, the temperature of the oxidizing gas should be lower than the temperature of the object to be processed (for example, 400° C.). In this manner, the silicon oxide film may be formed even though the temperature of the object to be processed is 400° C. or less.

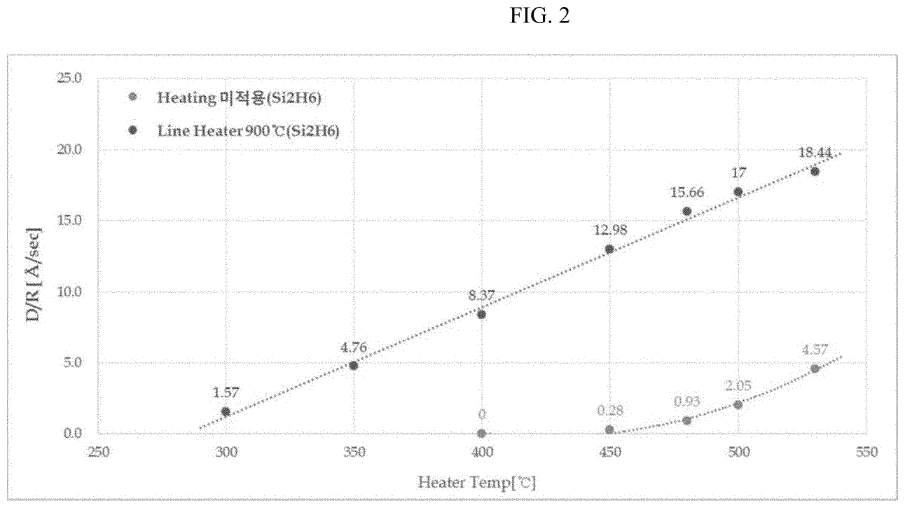

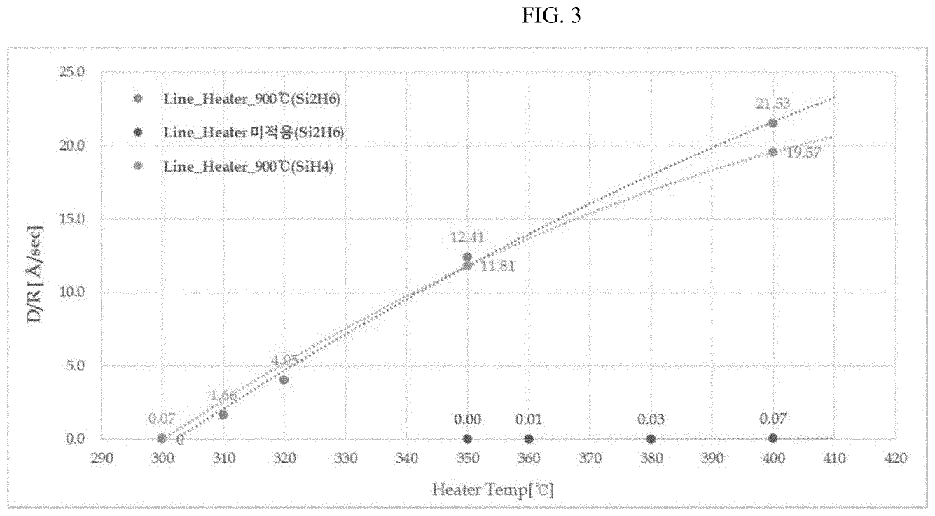

FIG. 2 and FIG. 3 are graphs showing thin film formation rates according to the temperature of an object to be processed when an oxidizing gas is heated and supplied and when an oxidizing gas is not heated and supplied. As shown in FIG. 2, when the temperature inside the chamber (or the temperature of the object to be processed) is 300-400° C., when the oxidizing gas is supplied without being heated, the silicon oxide film is not formed at all. On the other hand, when the oxidizing gas is heated through the line heater and supplied, even when the temperature of the object to be processed is 400° C. or less, the silicon oxide film is formed, and thin film formation rate (D/R) is 1.57 even at 300° C. Therefore, it can be seen that the silicon oxide film is formed even when the process temperature of the silicon oxide film (or the temperature of the object to be processed) is lowered to 300° C. Particularly, it can be seen that the thin film formation rate is generally linearly increased in accordance with the process temperature.

In addition, as shown in FIG. 3, when the temperature of the object to be processed is 300-350° C., when the oxidizing gas is supplied without being heated, the silicon oxide film is not formed at all. On the other hand, when the oxidizing gas is heated through the line heater and supplied, even when the temperature of the object to be processed is 400° C. or less, the silicon oxide film is formed. In the case of silane (SiH₄), the thin film formation rate (D/R) is 0.07 at 300° C., and in the case of disilane (Si₂H₆), the thin film formation rate (D/R) is 1.66 at 310° C. Therefore, it can be seen that the silicon oxide film is formed even when the process temperature of the silicon oxide film (or the temperature of the object to be processed) is lowered to less than 350° C. Particularly, it can be seen that the thin film formation rate is generally linearly increased in accordance with the process temperature.

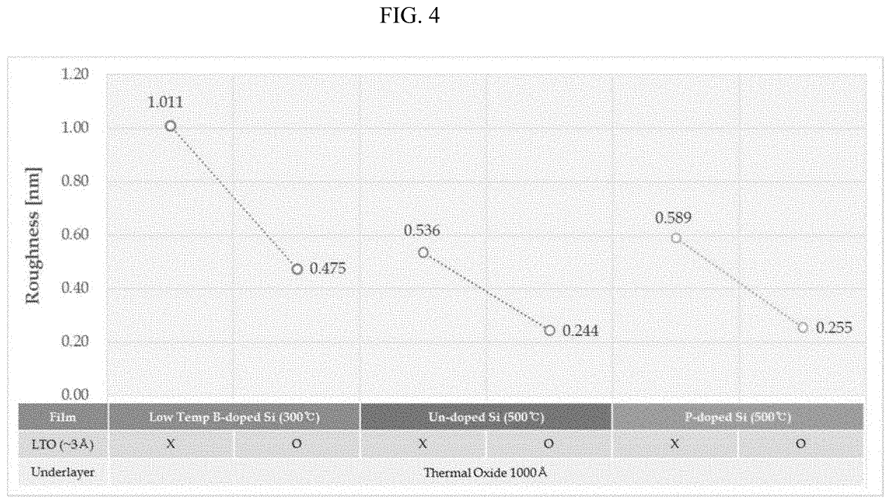

FIG. 4 is a graph showing the average roughness of a thin film with respect to the same underlayer. When of a thermal oxide film of 1000 Å is deposited with the underlayer and then a silicon oxide film (LTO) of 3 Å is deposited at less than 400° C. in the manner described above in which the oxidizing gas is heated and supplied and various upper films are formed thereon, it can be seen that the average roughness of the upper films is significantly improved.

Specifically, in the case in which an amorphous silicon film doped with boron at a low temperature was deposited on an upper portion of the underlayer at 300° C., when the silicon oxide film (LTO) was deposited, the average roughness was improved from 1.011 to 0.475. In addition, in the case in which an undoped amorphous silicon film was deposited on an upper portion of the underlayer at 500° C., when the silicon oxide film (LTO) was deposited, the average roughness was improved from 0.536 to 0.244. In addition, in the case in which an amorphous silicon film doped with phosphorus was deposited on an upper portion of the underlayer at 500° C., when the silicon oxide film (LTO) was deposited, the average roughness was improved from 0.589 to 0.255.

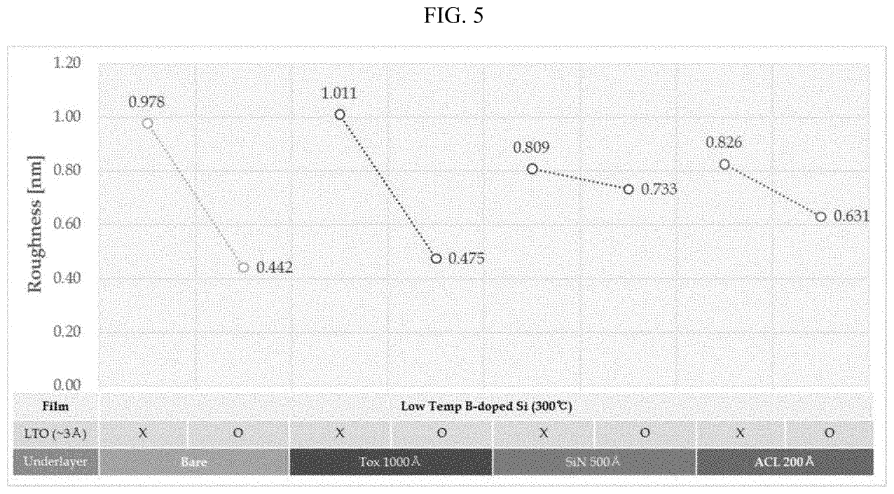

FIG. 5 is a graph showing the average roughness of a thin film with respect to various underlayers. With respect to various underlayers, when a silicon oxide film (LTO) of 3 Å is deposited at less than 400° C. in the manner described above in which the oxidizing gas is heated and supplied and an amorphous silicon film doped with boron at a low temperature was formed thereon at 300° C., it can be seen that the average roughness of an upper portion film is significantly improved.

Specifically, in the case in which the amorphous silicon film doped with boron at a low temperature was deposited on an upper portion of a bare object to be processed having no thin film, when the silicon oxide film (LTO) was deposited, the average roughness was improved from 0.978 to 0.442. In addition, in the case in which the amorphous silicon film doped with boron at a low temperature was deposited on an upper portion of a thermal oxide film of 1000 Å, when the silicon oxide film (LTO) was deposited, the average roughness was improved from 1.011 to 0.475. In addition, in the case in which the amorphous silicon film doped with boron was deposited on an upper portion of a nitric film of 500 Å which is the underlayer, when the silicon oxide film (LTO) was deposited, the average roughness was improved from 0.809 to 0.733. In addition, in the case in which a silicon film doped with boron at a low temperature was deposited on an upper portion of an amorphous carbon film (ACL) of 200 Å, when the silicon oxide film (LTO) was deposited, the average roughness was improved from 0.826 to 0.631.

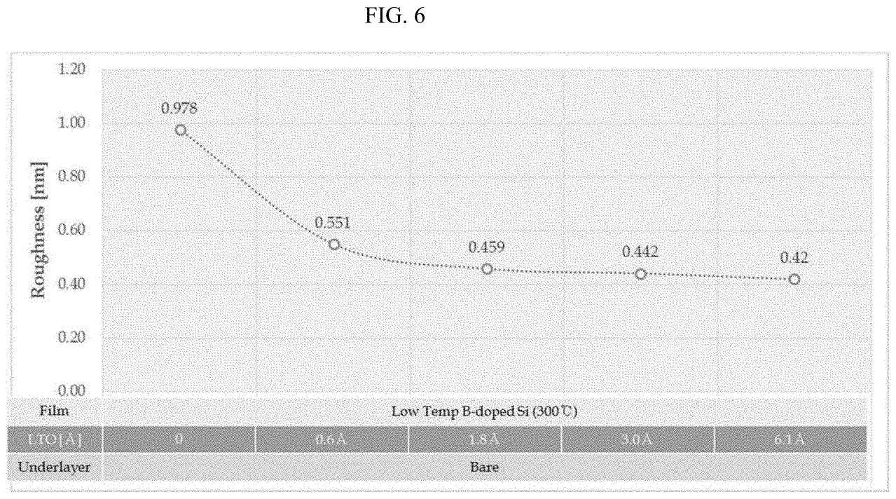

FIG. 6 is a graph showing the average roughness of a thin film in accordance with the thickness of a silicon oxide film. As shown in FIG. 6, when the amorphous silicon film doped with boron at a low temperature is deposited on an upper portion of a bare object to be processed having no thin film, it can be seen that the average roughness is improved as the thickness of the silicon oxide film (LTO) is increased.

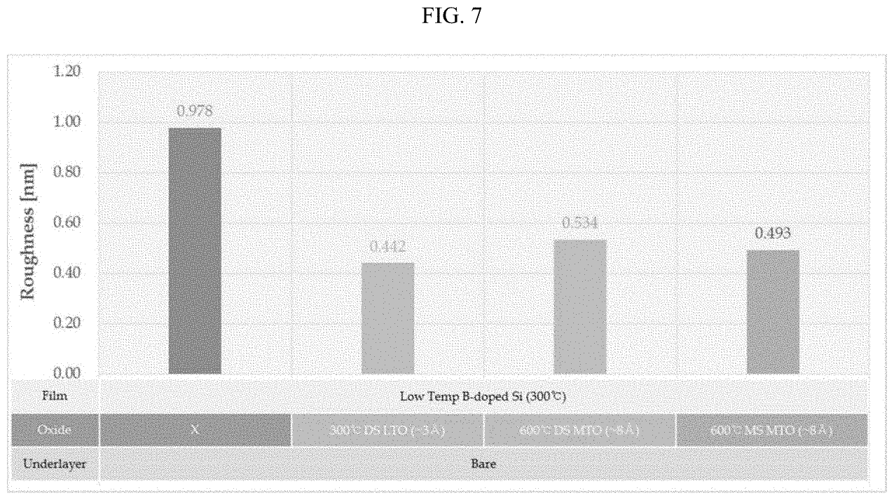

FIG. 7 is a graph showing the average roughness of a thin film in accordance with the process temperature (or the temperature of an object to be processed). As shown in FIG. 7, when the amorphous silicon film doped with boron at a low temperature was deposited on an upper portion of a bare object to be processed having no thin film, the average roughness differs in accordance with the process temperature (or the temperature of an object to be processed). Specifically, in the case in which the process temperature (or the temperature of an object to be processed) is 300° C., when the silicon oxide film (LTO) of 3 Å is formed using disilane, the average roughness is improved from 0.978 to 0.442. In addition, in the case in which the process temperature (or the temperature of an object to be processed) is 600° C., when the silicon oxide film (LTO) of 8 Å is formed using disilane, the average roughness is improved to 0.534, and in the case in which the process temperature (or the temperature of an object to be processed) is 600° C., when the silicon oxide film (LTO) of 8 Å is formed using monosilane, the average roughness is improved to 0.493.

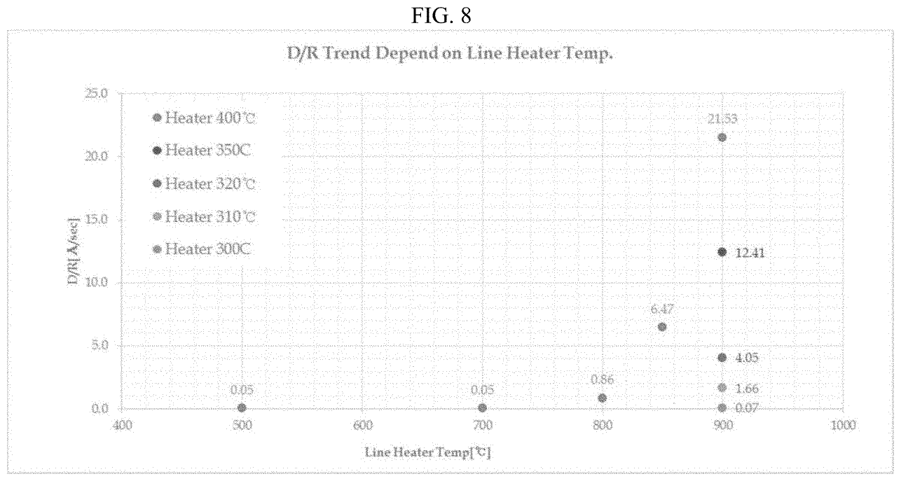

FIG. 8 is a graph showing the thin film formation rate according to the heating temperature of an oxidizing gas with respect to the temperature of various objects to be processed. As shown in FIG. 8, when the oxidizing gas is heated to 900° C. and supplied, it can be seen that the thin film formation rate in accordance with the process temperature (or the temperature of the object to be processed) is increased. In addition, when the process temperature is 400° C., it can be seen that the thin film formation rate is decreased as the heating temperature of the oxidizing gas is decreased. This is thought to be due to the decrease in the degree of pyrolysis of the oxidizing gas when the heating temperature of the oxidizing gas is decreased.

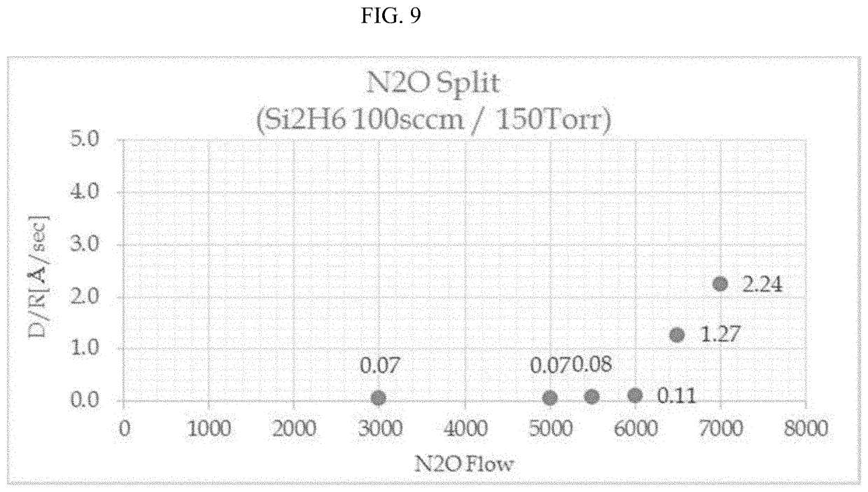

FIG. 9 is a graph showing the thin film formation rate in accordance with the flow rate of an oxidizing gas. As shown in FIG. 9, when the flow rate of the oxidizing gas is less than 6000 SCCM, the thin film formation rate is minimal. Therefore, it is preferable that the flow rate of the oxidizing gas is 6000 SCCM or greater.

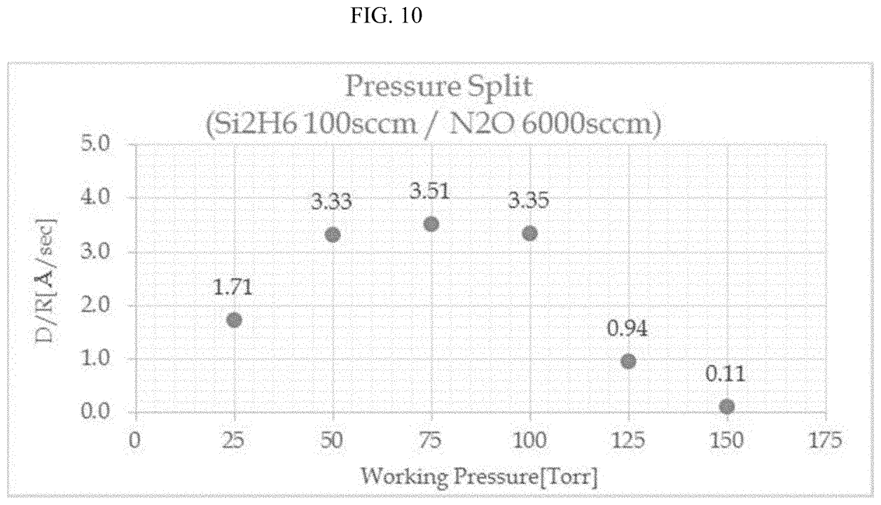

FIG. 10 is a graph showing the thin film formation rate in accordance with process pressure. As shown in FIG. 10, when the process pressure inside the chamber is 50-100 Torr, the thin film formation rate is high. Therefore, it is preferable that the process pressure is 50-100 Torr, but the process pressure may be 25 to 150 Torr as needed.

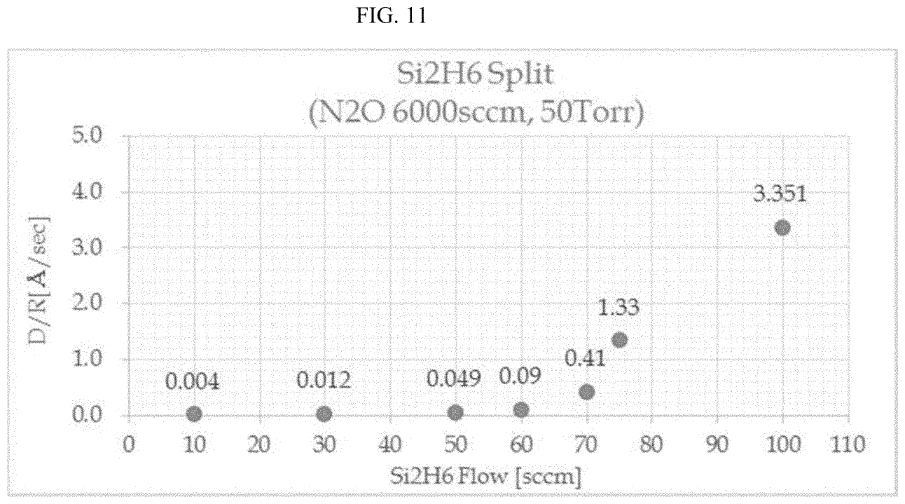

FIG. 11 is a graph showing the thin film formation rate in accordance with the flow rate of an Si source gas. As shown in FIG. 11, when the flow rate of disilane is less than 70 SCCM, the thin film formation rate is minimal. Therefore, it is preferable that the flow rate of disilane is 70-100 SCCM.

Meanwhile, in the present embodiment, an oxidizing gas is heated and supplied to form a silicon oxide film. However, in a similar manner, a nitriding gas (for example, NH₃) may be heated and supplied to form a silicon nitride film.

According to an embodiment of the present invention, a thin film may be formed at a temperature of 400° C. or less.

In addition, the surface roughness of a thin film may be lowered to less than 1.0.

Although the present invention has been described with reference to the specific embodiments, the present invention is not limited thereto. Therefore, it will be readily understood by those skilled in the art that various modifications and changes can be made thereto without departing from the spirit and scope of the present invention defined by the appended claims.

What is claimed is:

1. A method for forming a thin film, the method comprising:
loading an object to be processed into a chamber, and
while controlling the temperature of the object to be processed to be 400° C. or less, supplying an Si source gas and an oxidizing gas into the chamber to form a silicon oxide film on the surface of the object to be processed,
wherein the oxidizing gas is heated to a temperature exceeding 400° C. before being supplied into the chamber, and the oxidizing gas is supplied in a pyrolyzed state into the chamber at a temperature lower than the temperature of the object to be processed.

2. The method of claim 1, wherein the oxidizing gas is heated to a temperature of 700-900° C.

3. The method of claim 1, wherein the oxidizing gas is either N₂O or O₂, and the flow rate thereof supplied into the chamber is 3000-7000 SCCM.

4. The method of claim 1, wherein the Si source gas is either silane or disilane, and the flow rate thereof supplied into the chamber is 50-100 SCCM.

5. The method of claim 1, wherein the pressure inside the chamber is 25-150 Torr.

6. The method of claim 1, further comprising forming an upper thin film on an upper portion of the silicon oxide film, wherein the upper thin film is any one of an amorphous silicon thin film doped with boron (B), an undoped amorphous silicon thin film, and an amorphous silicon thin film doped with phosphorus (P).

7. The method of claim 6, wherein the silicon oxide film is 3 Å thick.

8. The method of claim 1, further comprising forming an underlayer before forming the silicon oxide film and then forming the silicon oxide film on an upper portion of the underlayer before, wherein the underlayer is any one of a thermal oxide film, a silicon nitride film, and an amorphous carbon film.

9. An apparatus for forming a thin film, the apparatus comprising:
a chamber having an internal space blocked from the outside and in which a process is performed in the internal space thereof;
a susceptor installed in the chamber to have an object to be processed placed thereon and having a built-in heater;
a silicon source gas supplier in which a silicon source gas is stored;
an oxidizing gas source supplier in which an oxidizing gas is stored;
a carrier gas supplier in which a carrier gas is stored;
a silicon source supply line connected to the silicon source gas supplier to supply the silicon source gas into the chamber;
a carrier gas supply line connected to the carrier gas supplier to supply the carrier gas into the chamber;
a main supply line connected to the silicon source supply line and the carrier gas supply line in the state of being connected to the chamber;
an oxidizing gas supply line connected to the main supply line to be connected to the oxidizing gas source supplier and supplying the oxidizing gas into the chamber; and
an oxidizing gas heater installed in the oxidizing gas supply line to heat the oxidizing gas to a temperature exceeding 400° C.
